(19) United States
(12) Patent Application Publication
(10) Pub. No.: US 2018/0190562 A1
(43) Pub. Date: Jul. 5, 2018

(54) ELECTRONIC DEVICE HAVING A GROOVED CHIP

(71) Applicants: STMicroelectronics (Tours) SAS, Tours (FR); STMicroelectronics (Grenoble 2) SAS, Grenoble (FR)

(72) Inventors: Laurent Figuiere, Grenoble (FR); Gaetan Lobascio, Moirans (FR); Alexandre Mas, Saint Egreve (FR)

(73) Assignees: STMicroelectronics (Tours) SAS, Tours (FR); STMicroelectronics (Grenoble 2) SAS, Grenoble (FR)

(21) Appl. No.: 15/689,828

(22) Filed: Aug. 29, 2017

(30) Foreign Application Priority Data
Jan. 3, 2017 (FR) 1750049

(51) Int. Cl. H01L 23/367; H01L 23/373; H01L 23/31; H01L 21/304; H01L 21/78; H01L 21/56

(52) U.S. Cl. CPC H01L 23/367; H01L 23/3733; H01L 23/3178; H01L 24/16; H01L 21/78; H01L 21/56; H01L 2224/16235; H01L 21/3043

(57) ABSTRACT

An electronic device includes a support plate having a mounting face. An electronic chip has a front face mounted on the mounting face of the support plate. A rear face of the electronic chip located opposite to the front face is provided with rear grooves that define, between the grooves, rear zones. A rear layer made of a heat-conducting material is spread over the rear face of the electronic chip so as to at least partly cover the rear zones and at least partially fill the rear grooves.

### PRIORITY CLAIM

This application claims the priority benefit of French Application for Patent No. 1750049, filed on Jan. 3, 2017, the disclosure of which is hereby incorporated by reference in its entirety to the maximum extent allowable by law.

### TECHNICAL FIELD

The present invention relates to the field of electronic devices including electronic chips.

### BACKGROUND

Some electronic chips produce heat. Many heat dissipation means, placed in the immediate environment of the chips, are known. Nevertheless, the trend of the technology is such that the quantity of heat to be discharged is increasingly significant.

There is a need in the art to improve the dissipation of the heat produced by electronic chips.

### SUMMARY

According to one embodiment, an electronic device is proposed which comprises a support plate which has a mounting face and an electronic chip which has a front face and a rear face opposite its front face and which is mounted on the support plate in a position such that the front face of the chip is facing the mounting face of the support plate.

The rear face of the chip is provided with a plurality of rear grooves, such that the rear face of the chip has, between said grooves, rear zones, and comprises a rear layer made of a heat-conducting material which is spread over the rear face of the chip so as to at least partially cover said rear zones and to at least partially fill said rear grooves.

Optionally, said rear layer made of a heat-conducting material can cover all of the rear face of the chip and can completely fill said rear grooves of the chip.

A heat-dissipating member can be attached to a rear face of said heat-conducting layer.

Said heat-dissipating member can comprise a plate forming a heat sink.

A cap can be provided to encapsulate the chip, in the form of a cup, this cap having a central part attached to said heat-conducting layer and having a peripheral part mounted on said support plate via a local fixing layer.

Said heat-conducting layer can comprise an epoxy resin filled with metal particles.

The chip can comprise, on the side of its front face, a layer including electronic components and electrical connection means.

Said grooves can be arranged in rows and columns.

The chip can be mounted on the support plate via electrical connection elements.

Also proposed is an electronic chip having a front face provided with electrical connection contact pads and a rear face, the rear face having a plurality of rear grooves and rear zones between these grooves, the rear face of the chip having, between said grooves, rear zones, said rear face being provided with a rear layer made of a heat-conducting material which is spread so as to at least partially cover said rear zones and at least partially fill said rear grooves.

Also proposed is a method for producing an electronic device, which comprises the following steps: mounting, on an adhesive sawing film, a semiconductor substrate comprising, on and in a front face, a plurality of electronic circuits, said front face facing said adhesive film; and sawing the rear face of the semiconductor substrate over a portion of its thickness and along a plurality of saw lines forming a plurality of grooves; sawing the semiconductor substrate over its entire thickness along dicing lines situated between said electronic circuits in order to obtain individual electronic chips; mounting an electronic chip on a support plate, in a position such that the front face of the electronic chip is facing the support plate, the rear face of the chip having rear zones separated by grooves; and spreading a rear layer made of a heat-conducting material over the rear face of the chip, so as to at least partly cover said rear zones and at least partially fill the rear grooves.

### BRIEF DESCRIPTION OF THE DRAWINGS

An electronic device will now be described in a non-limiting exemplary embodiment, illustrated by the attached drawing in which:

FIG. 1 represents a cross section of an electronic device;

FIG. 2 represents a rear view of an electronic chip of the electronic device of FIG. 1;

FIG. 3 represents a cross section of the electronic device of FIG. 1, provided with a heat dissipator; and

FIG. 4 represents a cross section of the electronic device of FIG. 1, provided with another heat dissipator.

### DETAILED DESCRIPTION

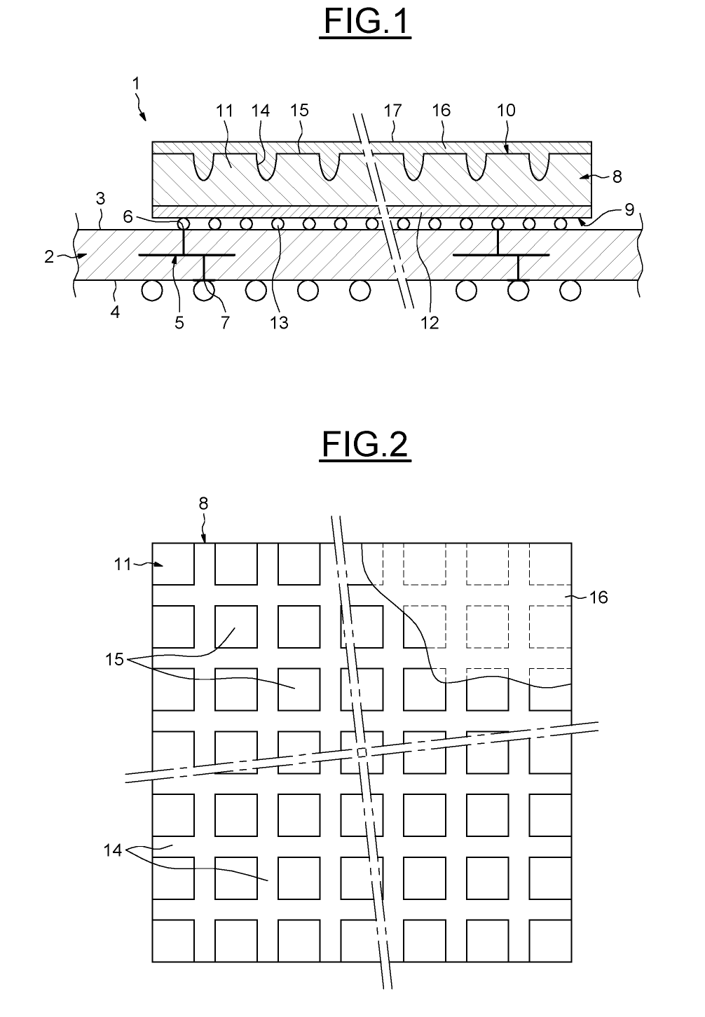

FIGS. 1 and 2 illustrate an electronic device 1 which comprises a support plate 2 made of a dielectric material, which has a front mounting face 3 and a rear face 4 which includes a network of electrical connections 5 having electrical contacts 6 on the front face 3 and electrical contacts 7 on the rear face 4.

The electronic device 1 comprises an electronic chip 8 which has a front face 9 and a rear face 10 opposite and parallel to its front face 9 and which comprises, on the side of its rear face 10, a substrate wafer 11, for example made of a semiconductor material such as silicon, and, on the side of its front face 9, a layer 12 including electronic components formed on the substrate wafer 11 and a network of electrical connections.

The electronic chip 8 is mounted on the support plate 2 in a position such that the front face 9 of the chip 8 is facing the mounting face 3 of the support plate 2, via soldered electrical connection elements 13, such as balls, which link the network of electrical connections of the layer 12 of the chip 8 and the front contact pads 6 of the support plate 2.

The rear face 10 of the chip 8 is provided with a plurality of rear grooves 14 which are formed in the substrate wafer 11, such that the rear face 10 of the chip 8 has, between the grooves 14, rear zones 15.

As an example illustrated in FIGS. 1 and 2, the rear grooves 14 constitute rows and columns of grooves extending parallel to the sides of the chip 8, in the form of a square matrix, and extend respectively from one edge to the other.

The rear grooves 14 can be produced by machining using a milling or sawing tool, laser equipment or by plasma etching.

Advantageously, the rear grooves 14 can be produced during a collective fabrication of a plurality of electronic chips 8, which comprises the following steps.

A semiconductor substrate wafer comprising, on and in a front face, a plurality of electronic circuits, is mounted on an adhesive sawing film, said front face facing said adhesive film.

The rear face of the semiconductor substrate wafer is sawed over a portion of its thickness and along a plurality of sawing lines forming a plurality of collective grooves.

Then, the semiconductor substrate wafer is then sawed over its entire thickness along dicing lines situated between said electronic circuits in order to obtain individual electronic chips 8, such that the rear face of each chip 8 has rear zones 15 separated by grooves 14 formed by portions of said collective grooves.

The electronic device 1 further comprises a rear layer 16, made of a heat-conducting material, which is spread over the rear face 10 of the chip 8, so as to cover the zones 15 of the rear face 10 of the chip 8 and to fill the rear grooves 14 of the chip 8, advantageously without discontinuity. The rear layer 16 has a rear face 17, for example flat, which is situated at a distance from the rear face 10 of the chip 8 and which determines its thickness above the rear zones 15 and above the rear grooves 14.

Thus, the heat flux passing from the chip 8 to the rear layer 16 takes place via the increased interface between the chip 8 and the rear layer 16, which comprises the rear zones 15 and the walls of the rear grooves 14. The heat flux captured by the rear layer 16 is discharged via the rear face 17 of this rear layer 16.

According to a variant embodiment, the rear grooves 16 could be produced on a local region of the rear face 10 of the chip 8 and the rear layer 16 could be limited to this region.

The heat-conducting rear layer 16 can be a suitable adhesive filled resin, in particular an epoxy resin filled with metal particles notably of copper or of aluminum. For its application, the substance can be spread in the liquid or pasty state over the rear face 10, then hardened.

According to a variant embodiment illustrated in FIG. 1, the rear face 17 of the heat-conducting rear layer 16 is exposed in the open air.

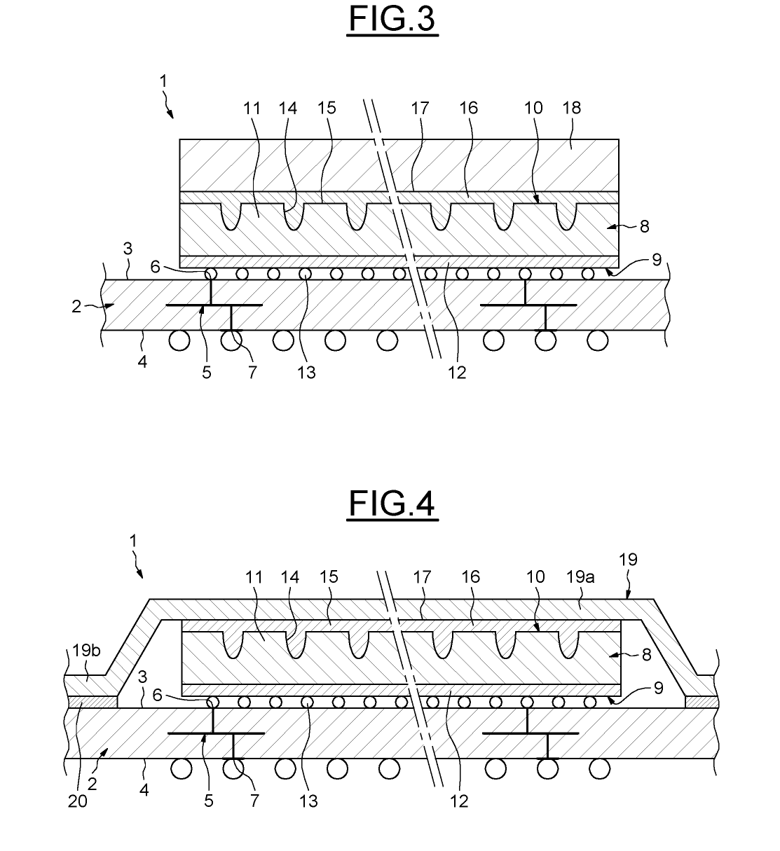

According to a variant embodiment illustrated in FIG. 3, the electronic device 1 comprises a heat-dissipating member 18, attached to the rear face 17 of the heat-conducting rear layer 16. According to an exemplary embodiment, the member 18 for dissipating the heat from the chip 8 via the rear layer 16 can take the form of a metal plate having a form adapted to constitute a heat sink.

According to a variant embodiment illustrated in FIG. 4, the electronic device 1 comprises a metal cap 19 for encapsulating the chip 8 above the support plate 2.

The encapsulation cap 19 takes the form of a cup and comprises a flat central part 19a attached to the rear face 17 of the heat-conducting rear layer 16 and an offset peripheral part 19b surrounding, at a distance, the periphery of the chip 8 and fixed onto the mounting face 3 of the support plate 2 via a local layer of glue 20, preferably a glue made of a heat-conducting material, for example similar to that of the rear layer 16. Thus, the encapsulation cap 19 constitutes a dissipator of the heat from the chip 8 via the rear layer 16.

According to a variant embodiment, the encapsulation cap 19 is metal and the local layer of glue 20 is also electrically conductive and is fixed onto the mounting face 3 of the support plate 2 at front contact pads 6 of the support plate 2, these front contact pads being connected to electrical contacts 7 on the rear face 4 via the network of electrical connections 5. The encapsulation cap 19 can thus be connected to the ground and also form an electromagnetic shielding for the chip 8.

1. An electronic device, comprising:
a support plate having a mounting face;
an electronic chip having a front face and a rear face opposite said front face, said electronic chip mounted to the support plate in a position such that the front face of the electronic chip faces the mounting face of the support plate, wherein the rear face of the chip includes a plurality of rear grooves defining in the rear face of the electronic chip, between said rear grooves, a plurality of rear zones; and
a rear layer made of a heat-conducting material spread over the rear face of the electronic chip so as to at least partially cover said rear zones and to at least partially fill said rear grooves.

2. The device according to claim 1, wherein said rear layer made of the heat-conducting material covers all of the rear face of the electronic chip and completely fills said rear grooves of the electronic chip.

3. The device according to claim 1, further comprising a heat-dissipating member attached to a rear face of said rear layer.

4. The device according to claim 3, wherein said heat-dissipating member comprises a plate forming a heat sink.

5. The device according to claim 1, further comprising a chip-encapsulating cap, in the form of a cup having a central part attached to a rear face of said rear layer and having a peripheral part having a surface mounted to the mounting face of said support plate via a local fixing layer.

6. The device according to claim 1, wherein said rear layer comprises an epoxy resin filled with metal particles.

7. The device according to claim 1, wherein the front face of said electronic chip comprises a layer including electronic components and electrical connection means.

8. The device according to claim 1, wherein said rear grooves are arranged in rows and columns.

9. The device according to claim 1, wherein the electronic chip is mounted on the support plate via electrical connection elements.

10. An electronic chip having a front face provided with electrical connection contact pads and a rear face, said rear face including a plurality of rear grooves defining in the rear face a plurality of rear zones between said rear grooves, and a rear layer made of a heat-conducting material spread over the rear face so as to at least partially cover said rear zones and at least partially fill said rear grooves.

11. The chip according to claim 10, wherein said rear layer made of the heat-conducting material covers all of the rear face and completely fills said rear grooves.

12. The chip according to claim 10, wherein said rear layer comprises an epoxy resin filled with metal particles.

13. The chip according to claim 10, wherein the front face further comprises electronic components electrically connected to said electrical contact pads.

14. The device according to claim 10, wherein said rear grooves are arranged in rows and columns.

15. A method for producing an electronic device, comprising the following steps:
mounting, on an adhesive sawing film, a semiconductor substrate wafer comprising, on and in a front face of said semiconductor substrate wafer, a plurality of electronic circuits, said front face facing said adhesive sawing film;
sawing a rear face of the semiconductor substrate wafer over a portion of a thickness of the semiconductor substrate wafer to form forming a plurality of rear grooves and a plurality of rear zones separated by said rear grooves;
sawing the semiconductor substrate over an entire thickness of the semiconductor substrate wafer along dicing lines situated between said electronic circuits in order to produce a plurality of separate individual electronic chips;
mounting each electronic chip of the plurality of separate individual electronic chips on a support plate, in a position such that a front face of the electronic chip faces the support plate; and
spreading a rear layer made of a heat-conducting material over a rear face of each electronic chip, so as to at least partly cover said rear zones and at least partially fill the rear grooves.

16. The method according to claim 15, wherein spreading comprises spreading the rear layer made of the heat-conducting material to cover all of the rear face of each electronic chip and completely fill said rear grooves of each electronic chip.

17. The method according to claim 15, further comprising mounting a heat-dissipating member in attachment to a rear face of said rear layer.

18. The method according to claim 17, wherein said heat-dissipating member comprises a plate forming a heat sink.

19. The method according to claim 15, wherein said rear layer comprises an epoxy resin filled with metal particles.

20. The method according to claim 15, wherein said rear grooves are arranged in rows and columns.
